(19) United States
(12) Patent Application Publication
(10) Pub. No.: US 2026/0363097 A1
(43) Pub. Date: Nov. 12, 2026

(54) FILM PACKAGE AND PACKAGE MODULE INCLUDING THE SAME

(71) Applicant: SAMSUNG ELECTRONICS CO., LTD., Suwon-si (KR)

(72) Inventor: Narae SHIN, Suwon-si (KR)

(73) Assignee: SAMSUNG ELECTRONICS CO., LTD., Suwon-si (KR)

(21) Appl. No.: 19/421,112

(22) Filed: Dec. 16, 2025

(30) Foreign Application Priority Data
May 9, 2025 (KR) 10-2025-0060715

(51) Int. Cl. H10W 70/40; H10W 90/00

(52) U.S. Cl. CPC H10W 70/453; H10W 70/421; H10W 70/479; H10W 90/724; H10W 90/734

(57) ABSTRACT

A film package includes a film substrate including a chip region, bypass regions spaced apart from one another in a first direction with the chip region therebetween, and a first edge and a second edge opposing each other in a second direction intersecting the first direction, first bypass pads arranged on the bypass region adjacent to the first edge and second bypass pads adjacent to the second edge, and a first bypass pattern connecting the first bypass pads and the second bypass pads.

### CROSS-REFERENCE TO RELATED APPLICATIONS

This U.S. non-provisional patent application claims priority under 35 U.S.C. § 119 of Korean Patent Application No. 10-2025-0060715, filed on May 9, 2025, the entire contents of which are hereby incorporated by reference.

### BACKGROUND

The present disclosure herein relates to a film package and a package module including the same.

Recently, chip-on-film (COF) package technology employing a flexible film substrate has been proposed in response to the trend of electronic products becoming smaller, thinner and lighter. In COF packaging, a semiconductor chip may be directly mounted onto a film substrate using a flip chip bonding method and connected to an external circuit via a short lead line. Such a COF package may be applied to panels of portable terminal devices such as cellular phones and PDAs, as well as laptop computers and display devices.

### SUMMARY

The present disclosure provides a film package with improved reliability.

The present disclosure also provides a package module with improved reliability.

The objects of the inventive concept are not limited to the aforementioned object, but other objects not described herein may be clearly understood by those skilled in the art from the following description.

An embodiment of the inventive concept provides a film package including a film substrate including a chip region, bypass regions spaced apart from one another in a first direction with the chip region therebetween, and a first edge and a second edge opposing each other in a second direction intersecting the first direction, first bypass pads arranged on the bypass region adjacent to the first edge and second bypass pads arranged on the bypass region adjacent to the second edge, and a first bypass pattern connecting the first bypass pads and the second bypass pads, wherein the first bypass pattern includes a first portion, a plurality of second portions extending from the first portion, connected to the first bypass pads, and spaced apart from one another, and a plurality of first recesses each defined between an adjacent pair of second portions among the plurality of first second portions, the second portions have a same first length in the second direction, a distance between outer side surfaces of second portions spaced farthest apart from each other among the second portions in the first direction is equal to a first width of the first portion In the first direction.

In an embodiment of the inventive concept, a film package includes a film substrate including a chip region, bypass regions spaced apart from one another in a first direction with the chip region disposed therebetween, and a first edge and a second edge opposing each other in a second direction intersecting the first direction, first bypass pads arranged on the bypass region adjacent to the first edge and second bypass pads arranged on the bypass region adjacent to the second edge, and first bypass patterns connecting the first bypass pads and the second bypass pads and spaced apart from one another in the first direction, wherein each of the first bypass patterns includes a first portion and a plurality of second portions extending from the first portion, connected to the first bypass pads, and spaced apart from one another, the second portions have a same first length in the second direction, and two or more of the first bypass patterns are continuously arranged on the film substrate.

In an embodiment of the inventive concept, a package module includes a circuit board, a display panel spaced apart from the circuit board, and a film package disposed between the circuit board and the display panel, wherein the film package includes a film substrate including a chip region, bypass regions spaced apart from one another in a first direction with the chip region disposed therebetween, and a first edge and a second edge opposing each other in a second direction intersecting the first direction, first connection pads arranged adjacent to the first edge and connected to the display panel and second connection pads arranged adjacent to the second edge and connected to the circuit board, on the chip region, a semiconductor chip disposed between the first and second connection pads on the chip region, first bypass pads arranged on the bypass region adjacent to the first edge and second bypass pads arranged on the bypass region adjacent to the second edge, and a first bypass pattern and a second bypass pattern connecting the first bypass pads and the second bypass pads, and spaced apart from each other in the first direction, the first bypass pattern includes a first portion, and a plurality of second portions extending from the first portion, connected to the first bypass pads, and spaced apart from one another, the second bypass pattern includes a third portion, and a plurality of fourth portions extending from the third portion and connected to the first bypass pads, the second portions have a same first length in the second direction, the fourth portions have a same second length in the second direction, and the first length is greater than the second length.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a schematic plan view of a film package according to embodiments of the inventive concept;

FIGS. 2A, 2B and 2C each are an enlarged view of portion P1 of FIG. 1;

FIGS. 3A and 3B each are an enlarged view of portion P1 of FIG. 1;

FIGS. 4A, 5A and 6A are plan views sequentially illustrating a process of manufacturing the film package of FIG. 1 according to embodiments of the inventive concept;

FIGS. 4B, 5B and 6B are enlarged views of portions P1 of FIGS. 4A, 5A and 6A, respectively;

FIGS. 4C, 5C and 6C are cross-sectional views taken along lines A-A′ of FIGS. 4B, 5B and 6B, respectively, according to embodiments of the inventive concept;

FIGS. 4D, 5D and 6D are enlarged views of portions P2 of FIGS. 4A, 5A and 6A, respectively;

FIG. 7 is an enlarged view of portion P1 of FIG. 1;

FIG. 8 is a plan view of a package module according to embodiments of the inventive concept; and

FIG. 9 is a cross-sectional view of a package module according to embodiments of the inventive concept.

### DETAILED DESCRIPTION

Hereinafter, embodiments according to the inventive concept will be described in detail with reference to the accompanying drawings in order to describe the inventive concept in more detail. As used herein, each of such phrases as “A or B”, “at least one of A and B”, “at least one of A or B”, “A, B, or C”, “at least one of A, B, and C”, and “at least one of A, B, or C” may include any one or all possible combinations of the items enumerated together in a corresponding one of the phrases. Herein, the terms indicating order, such as first, second, etc., are used to distinguish elements having the same/similar functions, and the ordinal numbers may be interchanged according to the order in which the terms are mentioned.

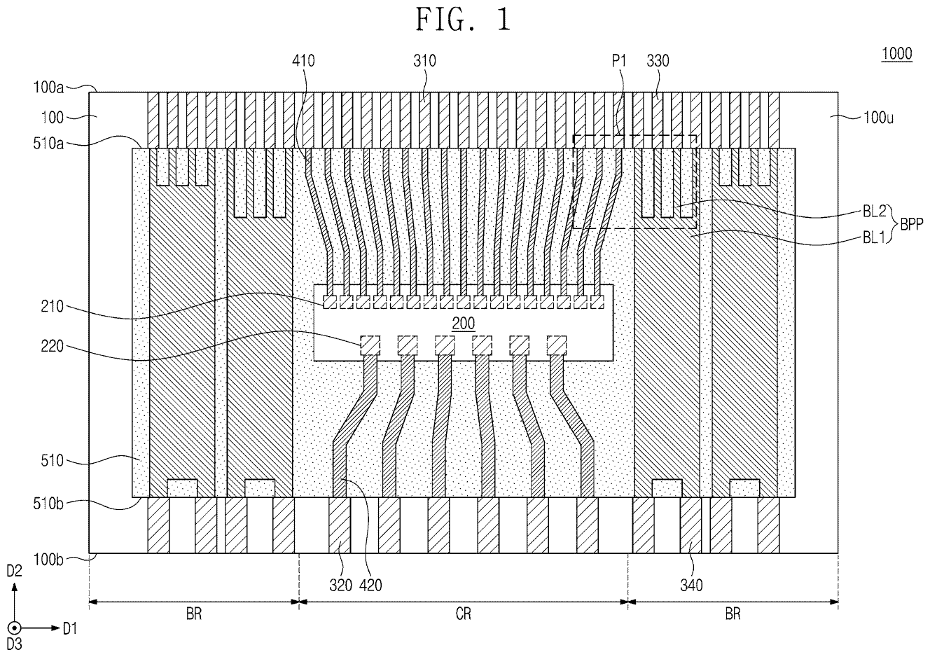

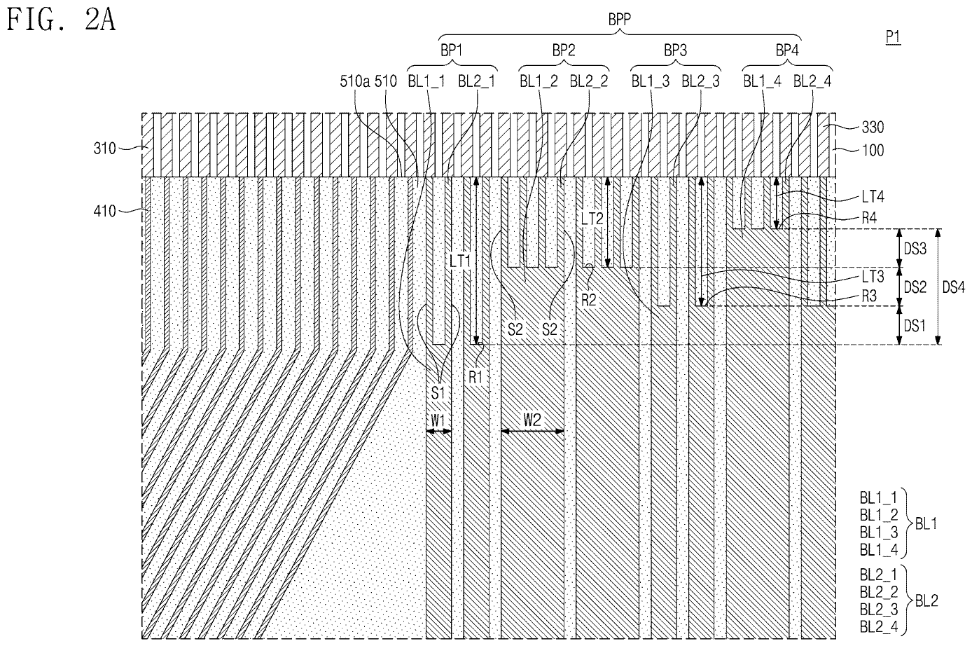

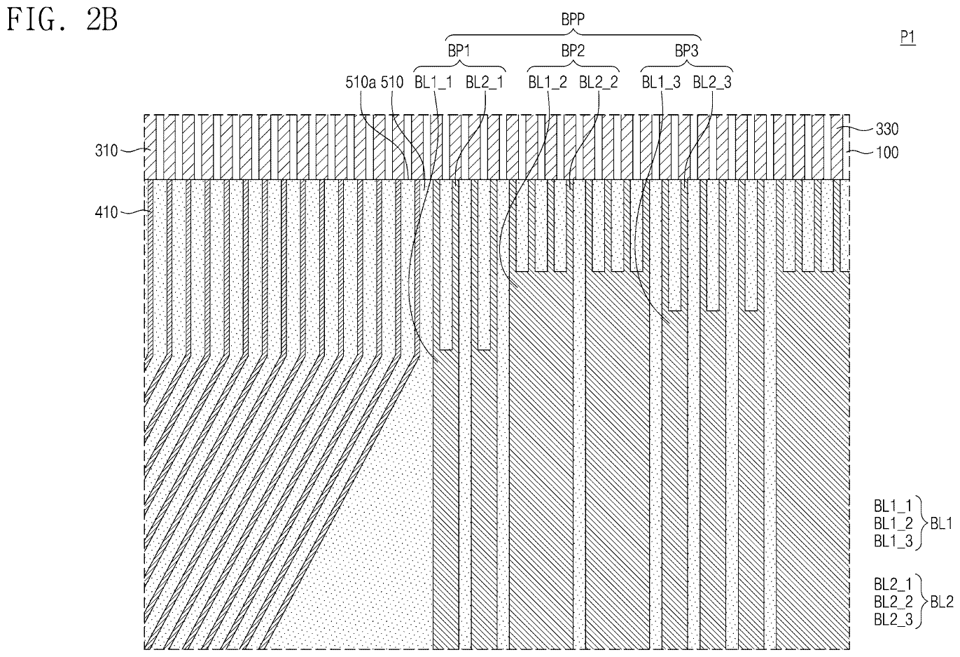

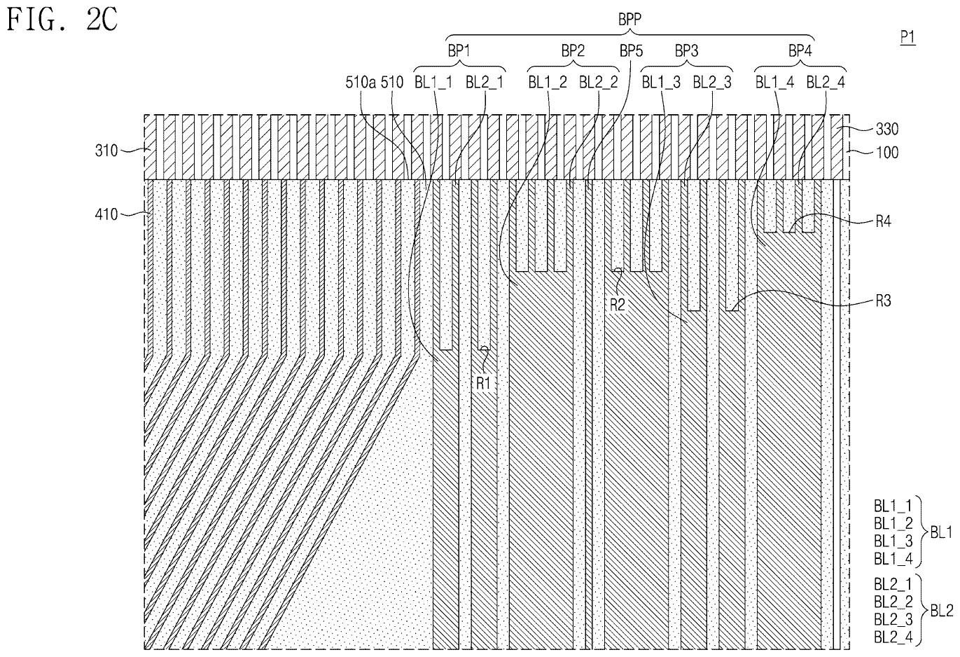

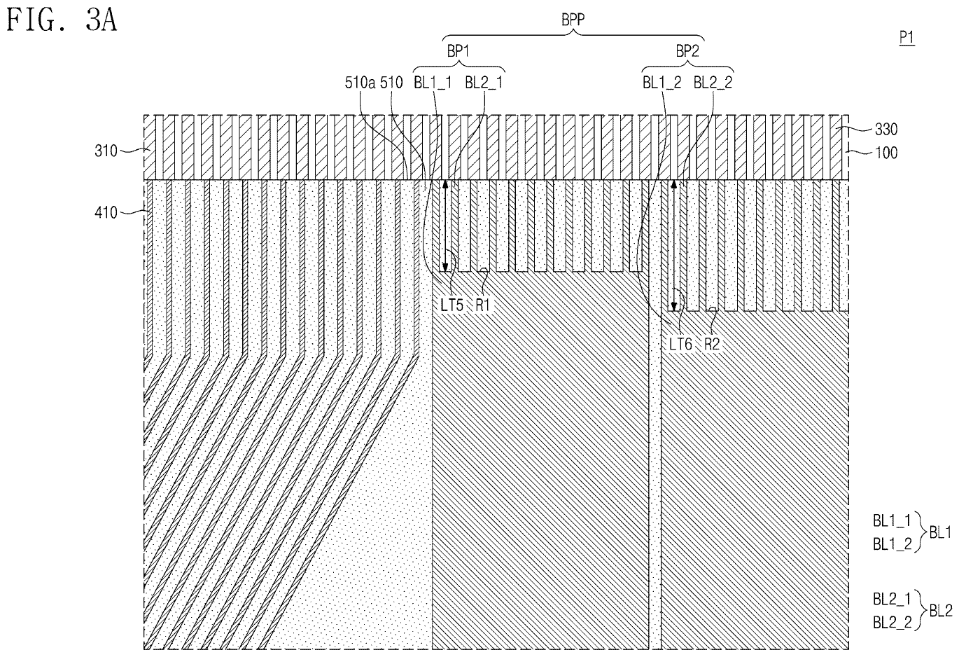

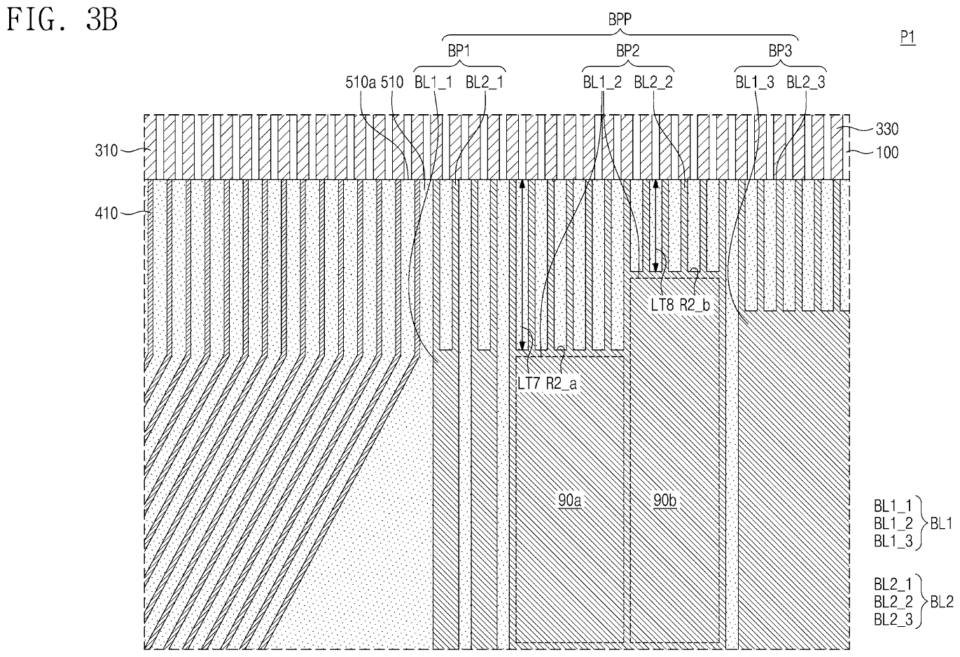

FIG. 1 is a schematic plan view of a film package according to embodiments of the inventive concept. FIGS. 2A, 2B and 2C each are an enlarged view of portion P1 of FIG. 1. FIGS. 3A and 3B each are an enlarged view of portion P1 of FIG. 1.

Referring to FIG. 1, a semiconductor package may include a film substrate 100, a semiconductor chip 200, first connection pads 310, second connection pads 320, first connection lines 410, second connection lines 420, first bypass pads 330, second bypass pads 340, bypass patterns BPP and a line protective layer 510.

The film substrate 100 may be a base film in which the semiconductor chip 200, the first connection pads 310, the second connection pads 320, the first connection lines 410, the second connection lines 420, the first bypass pads 330, the second bypass pads 340, the bypass patterns BPP and the line protective layer 510 are provided on a front surface 100u of the film substrate 100. The film substrate 100 may have a plate shape extending along a plane expanding in a first direction D1 and a second direction D2. The first direction D1 and the second direction D2 may intersect each other. For example, the first direction D1 and the second direction D2 may be horizontal directions perpendicular to each other. The film substrate 100 may include a chip region CR and bypass regions BR. For example, the chip region CR may be a region in which the semiconductor chip 200 is mounted. The bypass regions BR may be spaced apart from each other in the first direction D1 with the chip region CR therebetween. The film substrate 100 may include a first edge 100a and a second edge 100b opposing each other in the second direction D2.

The film substrate 100 may include a polymer material. For example, the film substrate 100 may include polyimide. The film substrate 100 may be a flexible substrate. The film substrate 100 may be bendable. Although not shown, the film substrate 100 may include a plurality of sprocket holes. In a plan view, the sprocket holes may be arranged along the second direction D2 on an outer side of the bypass regions BR of the film substrate 100. A film package 1000 may be wound or unwound by using the sprocket holes.

The semiconductor chip 200 may be disposed on the front surface 100u of the film substrate 100 on the chip region CR. The semiconductor chip 200 may have an upper surface and a lower surface opposing each other. The semiconductor chip 200 may include first chip pads 210 and second chip pads 220 arranged on the lower surface of the semiconductor chip 200. The first chip pads 210 may be spaced apart from each other along the first direction D1. The second chip pads 220 may be spaced apart from each other along the first direction D1. The first chip pads 210 and the second chip pads 220 may be spaced apart from each other along the second direction D2. The first chip pads 210 and the second chip pads 220 may include a conductive material. For example, the first chip pads 210 and the second chip pads 220 may include at least one of copper (Cu), gold (Au), nickel (Ni), tin (Sn), silver (Ag), tungsten (W) or aluminum (Al).

The semiconductor chip 200 may be, for example, a display driver IC which drives a display panel. For example, the semiconductor chip 200 may generate an image signal by using a data signal transmitted from a timing controller and output the image signal to the display panel. According to some embodiments, the semiconductor chip 200 may be a timing controller connected to a display driver IC.

The first connection pads 310 and the second connection pads 320 may be arranged on the front surface 100u of the film substrate 100 on the chip region CR. The first connection pads 310 may be arranged adjacent to the first edge 100a of the film substrate 100. The second connection pads 320 may be arranged adjacent to the second edge 100b of the film substrate 100. The first connection pads 310 may be spaced apart from each other in the first direction D1. The second connection pads 320 may be spaced apart from each other in the first direction D1. The first connection pads 310 and the second connection pads 320 may be spaced apart from each other along the second direction D2 with the semiconductor chip 200 therebetween. For example, the first connection pads 310 may be output pads, and the second connection pads 320 may be input pads. The first connection pads 310 and the second connection pads 320 may include a conductive material. For example, the first connection pads 310 and the second connection pads 320 may include at least one of copper (Cu), gold (Au), nickel (Ni), tin (Sn), silver (Ag), tungsten (W) or aluminum (Al).

The first connection lines 410 and the second connection lines 420 may be arranged on the front surface 100u of the film substrate 100 on the chip region CR. The first connection lines 410 may be spaced apart from each other along the first direction D1. Intervals between the first connection lines 410 may increase in a direction away from the semiconductor chip 200. The second connection lines 420 may be spaced apart from each other along the first direction D1. Intervals between the second connection lines 420 may increase in a direction away from the semiconductor chip 200. The first connection lines 410 and the second connection lines 420 may include a conductive material. For example, the first connection lines 410 and the second connection lines 420 may include at least one of copper (Cu), gold (Au), nickel (Ni), tin (Sn), silver (Ag), tungsten (W) or aluminum (Al).

The first chip pads 210 of the semiconductor chip 200 may be connected to the first connection pads 310 via the first connection lines 410. That is, the first connection line 410 may connect the first chip pad 210 of the semiconductor chip 200 and the first connection pad 310 corresponding thereto. The second chip pads 220 of the semiconductor chip 200 may be connected to the second connection pads 320 via the second connection lines 420. That is, the second connection line 420 may connect the second chip pad 220 of the semiconductor chip 200 and the second connection pad 320 corresponding thereto.

The first bypass pads 330 and the second bypass pads 340 may be arranged on the front surface 100u of the film substrate 100 on each of the bypass regions BR. The first bypass pads 330 may be arranged adjacent to the first edge 100a of the film substrate 100. The second bypass pads 340 may be arranged adjacent to the second edge 100b of the film substrate 100. The first bypass pads 330 may be spaced apart from each other in the first direction D1. The second bypass pads 340 may be spaced apart from each other in the first direction D1. The first bypass pads 330 and the second bypass pads 340 may be spaced apart from each other along the second direction D2 with the bypass patterns BPP therebetween. The first bypass pads 330 and the second bypass pads 340 may include a conductive material. For example, the first bypass pads 330 and the second bypass pads 340 may include at least one of copper (Cu), gold (Au), nickel (Ni), tin (Sn), silver (Ag), tungsten (W) or aluminum (Al).

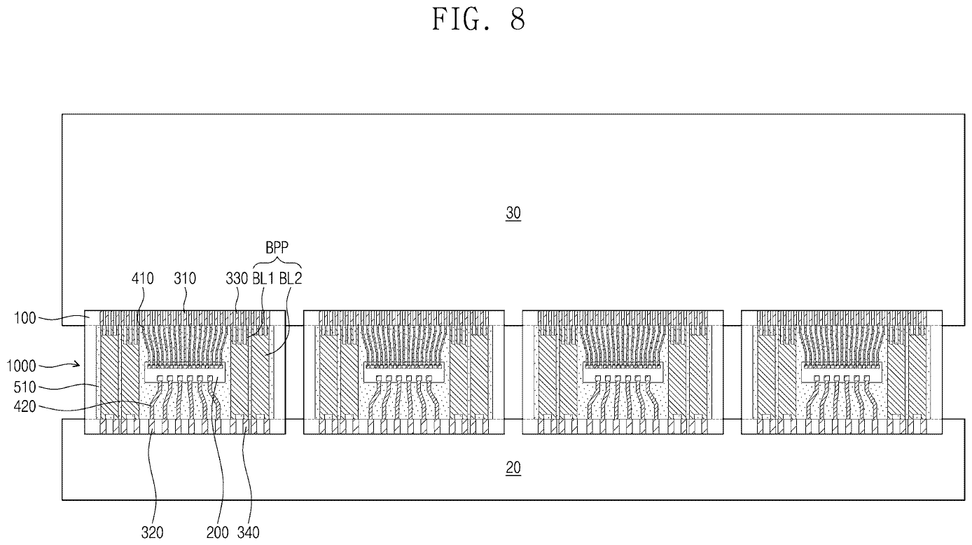

The bypass patterns BPP may be arranged on the front surface 100u of the film substrate 100 on each of the bypass regions BR. The bypass patterns BPP may be spaced apart from each other along the first direction D1. The bypass patterns BPP may be spaced apart from the first and second connection lines 410 and 420 along the first direction D1. The bypass patterns BPP may connect the first bypass pads 330 and the second bypass pads 340. The bypass patterns BPP may be lines for connecting a display element 30 (see FIG. 8) and a circuit board 20 (see FIG. 8) without going through the semiconductor chip 200.

The bypass patterns BPP may each include a pattern part BL1 and a line part BL2. The line part BL2 may extend from the pattern part BL1 in the second direction D2 and may be connected to the first bypass pads 330. The bypass patterns BPP may include a conductive material. For example, the bypass patterns BPP may include at least one of copper (Cu), gold (Au), nickel (Ni), tin (Sn), silver (Ag), tungsten (W) or aluminum (Al). The bypass patterns BPP will be described later below in more detail.

The line protective layer 510 may be provided on the film substrate 100. The line protective layer 510 may be disposed on the first connection lines 410, the second connection lines 420 and the bypass patterns BPP. The line protective layer 510 may cover the first connection lines 410, the second connection lines 420 and the bypass patterns BPP. The line protective layer 510 may expose the first connection pads 310, the second connection pads 320, the first bypass pads 330 and the second bypass pads 340. The line protective layer 510 may not cover the semiconductor chip 200. The line protective layer 510 may include a third edge 510a adjacent to the first connection pads 310 and a fourth edge 510b adjacent to the second connection pads 320.

The line protective layer 510 may include an insulating material. For example, the line protective layer 510 may include a solder resist material. The line protective layer 510 may protect the first connection lines 410, the second connection lines 420 and the bypass patterns BPP. For example, the line protective layer 510 may prevent oxidation or short circuit, which may occur in a heat treatment process, of the first connection lines 410, the second connection lines 420 and the bypass patterns BPP.

Although not shown, test pads may be further arranged on the film substrate 100. The test pads may be spaced apart from the semiconductor chip 200, the first connection pads 310, the second connection pads 320, the first connection lines 410, the second connection lines 420, the first bypass pads 330, the second bypass pads 340 and the bypass patterns BPP. Characteristics of the semiconductor chip 200 may be inspected by using the test pads. For example, the characteristics of the semiconductor chip 200 may be inspected by using a measuring device including a probe.

Referring to FIGS. 1 and 2A, according to an embodiment, the bypass patterns BPP may include first to fourth bypass patterns BP1, BP2, BP3 and BP4. The first to fourth bypass patterns BP1, BP2, BP3 and BP4 may be spaced apart from each other along the first direction D1.

The first bypass pattern BP1 may include a first portion BL1_1 and a plurality of second portions BL2_1. The first bypass pattern BP1 may include, for example, one first portion BL1_1 and two to twenty second portions BL2_1. However, an embodiment of the inventive concept is not limited thereto, and the first bypass pattern BP1 may include twenty or more second portions BL2_1.

The first portion BL1_1 may have a greater width than the second portion BL2_1 in the first direction D1. The second portions BL2_1 may be spaced apart from each other along the first direction D1. A distance between first outer side surfaces S1 of the second portions BL2_1 spaced farthest apart from each other among the second portions BL2_1 in the first direction D1 may be equal to a first width W1 of the first portion BL1_1. The second portions BL2_1 may extend from the first portion BL1_1 and may be connected to the first bypass pads 330. The second portions BL2_1 may have the same first length LT1. A first recess R1 may be formed between the second portions BL2_1 of the first bypass pattern BP1. The first recess R1 may have the first length LT1 from ends of the second portions BL2-1. The line protective layer 510 may fill the first recess R1. The first bypass pattern BP1 may be provided in plurality.

The second bypass pattern BP2 may include a third portion BL1_2 and a plurality of fourth portions BL2_2. The second bypass pattern BP2 may include, for example, one third portion BL1_2 and two to twenty fourth portions BL2_2. However, an embodiment of the inventive concept is not limited thereto, and the second bypass pattern BP2 may include twenty or more fourth portions BL2_2.

The third portion BL1_2 may have a greater width than the fourth portion BL2_2 in the first direction D1. The fourth portions BL2_2 may be spaced apart from each other along the first direction D1. A distance between second outer side surfaces S2 of the fourth portions BL2_2 spaced farthest apart from each other among the fourth portions BL2_2 in the first direction D1 may be equal to a second width W2 of the third portion BL1_2. The fourth portions BL2_2 may extend from the third portion BL1_2 and may be connected to the first bypass pads 330. The fourth portions BL2_2 may have the same second length LT2. A second recess R2 may be formed between the fourth portions BL2_2 of the second bypass pattern BP2. The second recess R2 may have the second length LT2 from ends of the fourth portions BL2_2. The first length LT1 may be greater than the second length LT2. The line protective layer 510 may fill the second recess R2. The second bypass pattern BP2 may be provided in plurality.

The third bypass pattern BP3 may include a fifth portion BL1_3 and a plurality of sixth portions BL2_3. The third bypass pattern BP3 may include, for example, one fifth portion BL1_3 and two to twenty sixth portions BL2_3. However, an embodiment of the inventive concept is not limited thereto, and the third bypass pattern BP3 may include twenty or more sixth portions BL2_3.

The fifth portion BL1_3 may have a greater width than the sixth portion BL2_3 in the first direction D1. The sixth portions BL2_3 may be spaced apart from each other along the first direction D1. The sixth portions BL2_3 may extend from the fifth portion BL1_3 and may be connected to the first bypass pads 330. The sixth portions BL2_3 may have the same third length LT3. A third recess R3 may be formed between the sixth portions BL2_3 of the third bypass pattern BP3. The third recess R3 may have the third length LT3 from ends of the sixth portions BL2_3. The third length LT3 may be smaller than the first length LT1 and greater than the second length LT2. The line protective layer 510 may fill the third recess R3. The third bypass pattern BP3 may be provided in plurality.

The fourth bypass pattern BP4 may include a seventh portion BL1_4 and a plurality of eighth portions BL2_4. The fourth bypass pattern BP4 may include, for example, one seventh portion BL1_4 and two to twenty eighth portions BL2_4. However, an embodiment of the inventive concept is not limited thereto, and the fourth bypass pattern BP4 may include twenty or more eighth portions BL2_4.

The seventh portion BL1_4 may have a greater width than the eighth portion BL2_4 in the first direction D1. The eighth portions BL2_4 may be spaced apart from each other along the first direction D1. The eighth portions BL2_4 may extend from the seventh portion BL1_4 and may be connected to the first bypass pads 330. The eighth portions BL2_4 may have the same fourth length LT4. A fourth recess R4 may be formed between the eighth portions BL2_4 of the fourth bypass pattern BP4. The fourth recess R4 may have the fourth length LT4 from ends of the eighth portions BL2_4. The fourth length LT4 may be smaller than the first to third lengths LT1, LT2 and LT3. The line protective layer 510 may fill the fourth recess R4. The fourth bypass pattern BP4 may be provided in plurality.

Each of a first distance DS1 between one side surface of the first recess R1 adjacent to the first portion BL1_1 and one side surface of the third recess R3 adjacent to the fifth portion BL1_3, a second distance DS2 between one side surface of the second recess R2 adjacent to the third portion BL1_2 and one side surface of the third recess R3 adjacent to the fifth portion BL1_3, a third distance DS3 between one side surface of the second recess R2 adjacent to the third portion BL1_2 and one side surface of the fourth recess R4 adjacent to the seventh portion BL1_4 and a fourth distance DS4 between one side surface of the first recess R1 adjacent to the first portion BL1_1 and one side surface of the fourth recess R4 adjacent to the seventh portion BL1_4 may be, for example, about 50 μm to about 500 μm. In one or more aspects, the terms “substantially,” “about,” and “approximately” may provide an industry-accepted tolerance for their corresponding terms and/or relativity between items, such as a tolerance of ±1%, ±5%, or ±10% of the actual value stated, and other suitable tolerances.

That is, respective differences between the first to fourth lengths LT1, LT2, LT3 and LT4 of the second, fourth, sixth and eighth portions BL2_1, BL2_2, BL2_3 and BL2_4 may be about 50 μm to about 500 μm and specifically about 50 μm to about 100 μm. Since lengths of the second, fourth, sixth and eighth portions BL2_1, BL2_2, BL2_3 and BL2_4 are different from each other, stress may be distributed, and thus a crack or disconnection of the bypass patterns BPP due to bending stress may be prevented. Accordingly, a film package with improved reliability may be provided.

The first, third, fifth and seventh portions BL1_1, BL1_2, BL1_3 and BL1_4 may constitute the pattern part BL1 of the bypass pattern BPP. The second, fourth, sixth and eighth portions BL2_1, BL2_2, BL2_3 and BL2_4 may constitute the line part BL2 of the bypass pattern BPP.

Referring to FIGS. 1 and 2B, according to an embodiment, two first bypass patterns BP1 may be arranged adjacent to each other. Another bypass pattern may not be disposed between the two first bypass patterns BP1 adjacent to each other. Three third bypass patterns BP3 may be arranged adjacent to each other. Another bypass pattern may not be disposed between the three third bypass patterns BP3 adjacent to each other. The first bypass patterns BP1 may be spaced apart from each other, and the third bypass patterns BP3 may be spaced apart from each other. That is, the first bypass pattern BP1 having two second portions BL2_1 may be provided in plurality, and two or more of first bypass patterns BP1 may be continuously arranged. The third bypass pattern BP3 having two sixth portions BL2_3 may be provided in plurality, and two or more of third bypass patterns BP3 may be continuously arranged. Other configurations may be the same as/similar to those described with reference to FIGS. 1 and 2A.

Referring to FIGS. 1 and 2C, according to an embodiment, a fifth bypass pattern BP5 may be disposed between second bypass patterns BP2. The fifth bypass pattern BP5 may have a shape of one line extending along the second direction D2. Unlike the illustration, one or more fifth bypass patterns BP5 may be further arranged between the bypass patterns BPP. Other configurations may be the same as/similar to those described with reference to FIGS. 1 and 2A.

Referring to FIGS. 1 and 3A, according to an embodiment, a first bypass pattern BP1 may include one first portion BL1_1 and ten or more second portions BL2_1. The second portions BL2_1 may have the same fifth length LT5. A second bypass pattern BP2 may include one third portion BL1_2 and ten or more fourth portions BL2_2. The fourth portions BL2_2 may have the same sixth length LT6. Other configurations may be the same as/similar to those described with reference to FIGS. 1 and 2A.

Referring to FIGS. 1 and 3B, according to an embodiment, a third portion BL1_2 of a second bypass pattern BP2 may include a first sub-portion 90a and a second sub-portion 90b. Fourth portions BL2_2 connected to the first sub-portion 90a may have the same seventh length LT7. Fourth portions BL2_2 connected to the second sub-portion 90b may have the same eighth length LT8. The seventh length LT7 may be greater than the eighth length LT8. That is, when the second bypass pattern BP2 includes one third portion BL1_2 and ten or more fourth portions BL2_2, the fourth portions BL2_2 may have two different lengths. Second recesses R2_a and R2_b may be formed between the fourth portions BL2_2 connected to the first sub-portion 90a and between the fourth portions BL2_2 connected to the second sub-portion 90b, respectively. Other configurations may be the same as/similar to those described with reference to FIGS. 1 and 2A.

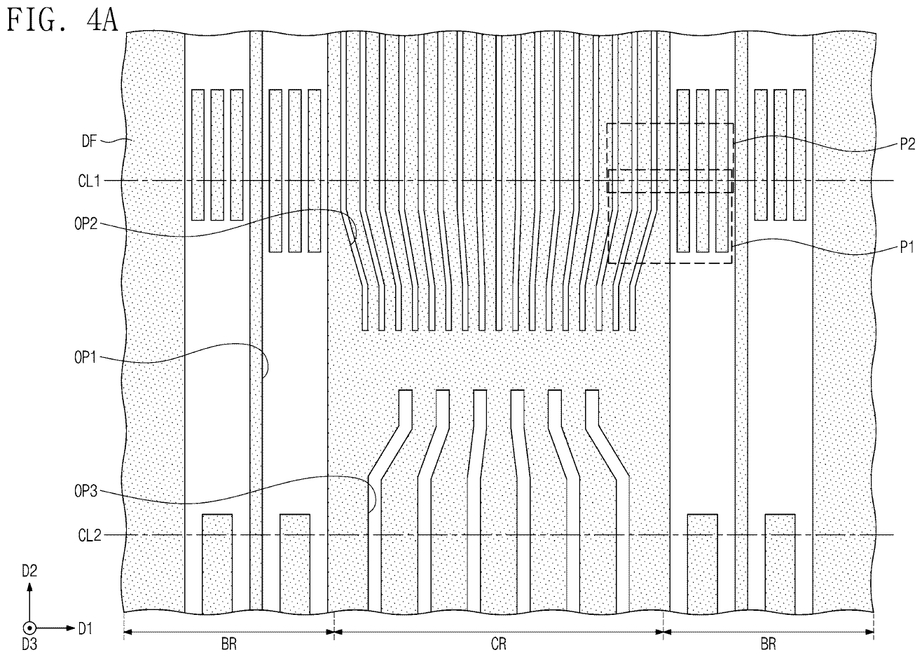

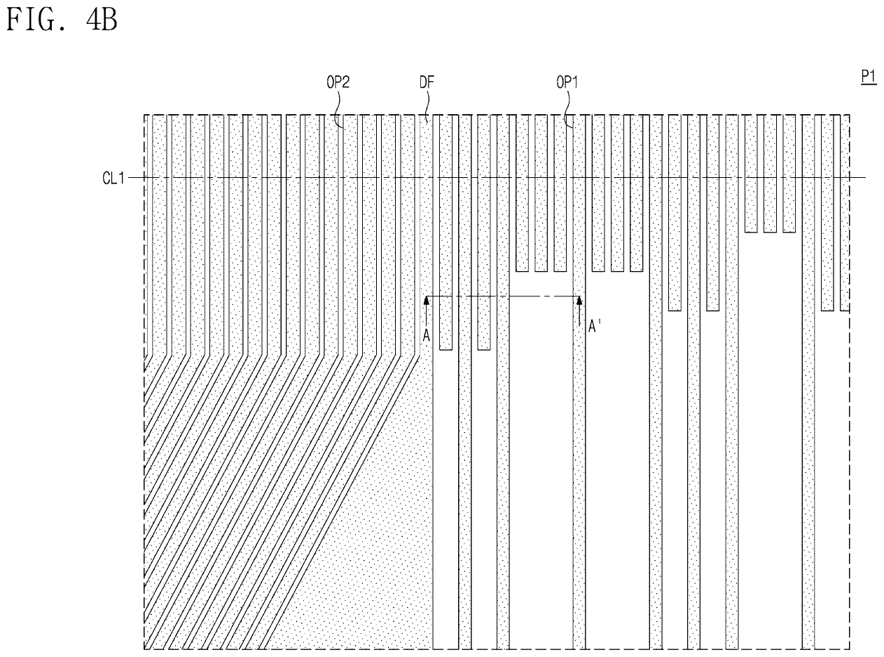

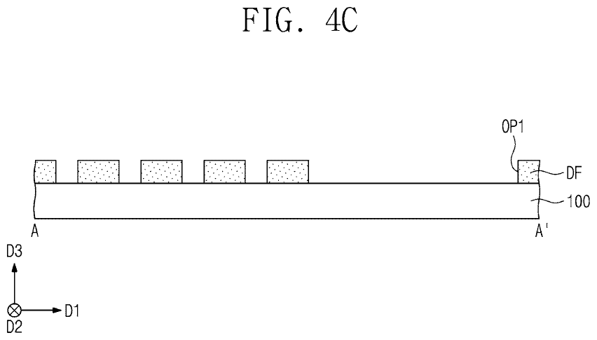

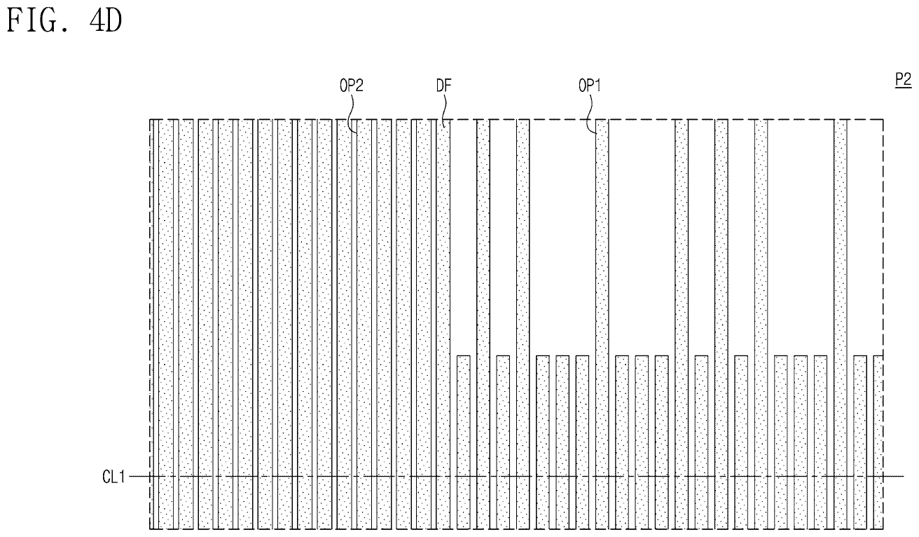

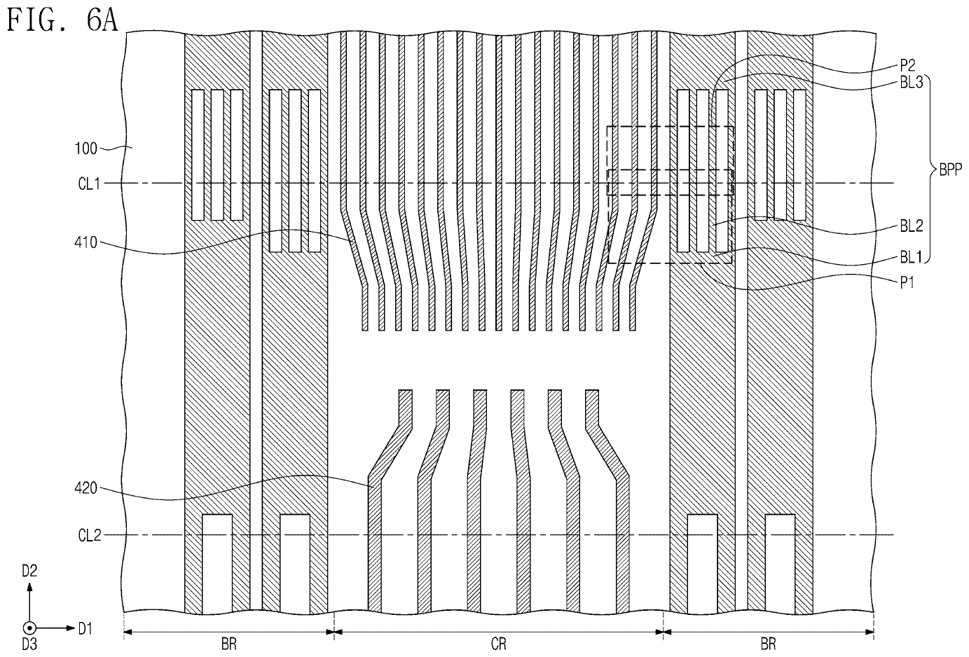

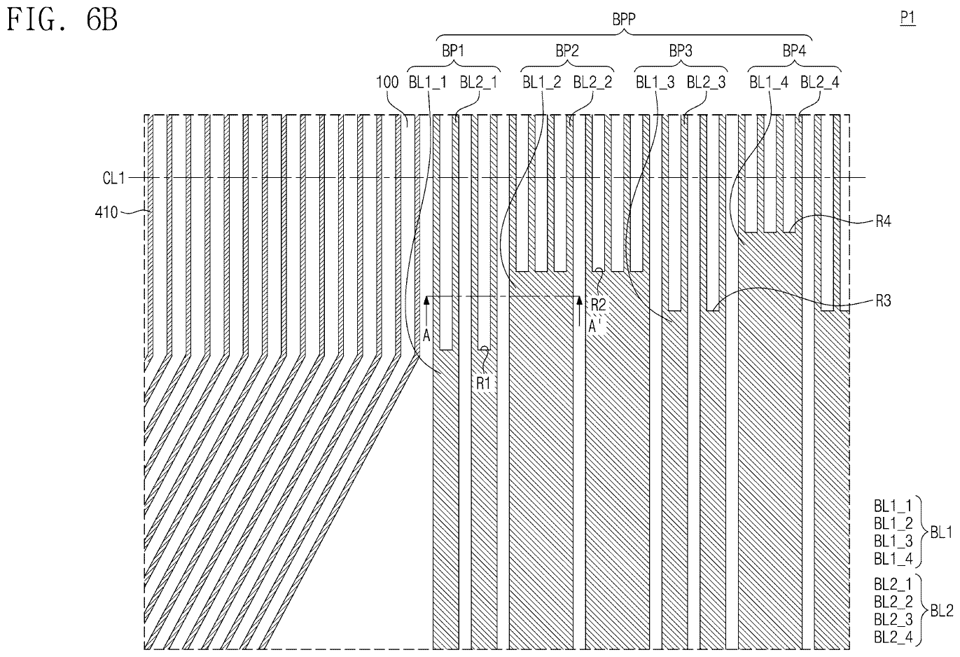

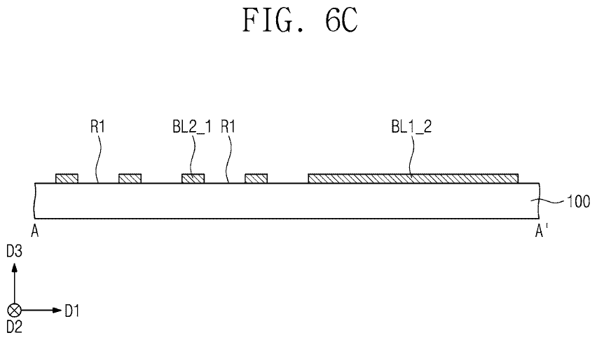

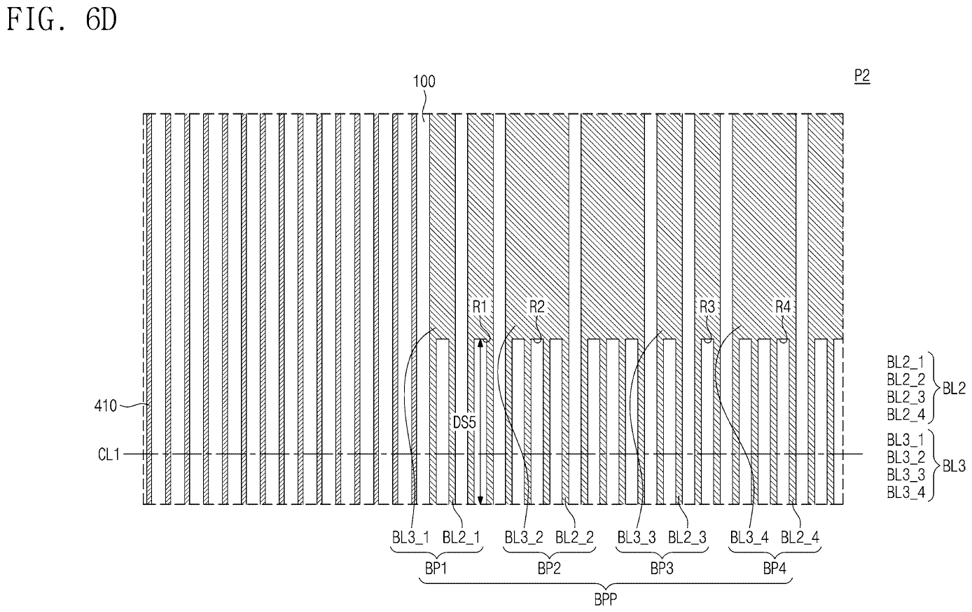

FIGS. 4A, 5A and 6A are plan views sequentially illustrating a process of manufacturing the film package of FIG. 1 according to embodiments of the inventive concept. FIGS. 4B, 5B and 6B are enlarged views of portions P1 of FIGS. 4A, 5A and 6A, respectively. FIGS. 4C, 5C and 6C are cross-sectional views taken along lines A-A′ of FIGS. 4B, 5B and 6B, respectively, according to embodiments of the inventive concept. FIGS. 4D, 5D and 6D are enlarged views of portions P2 of FIGS. 4A, 5A and 6A, respectively. For simplification of descriptions, descriptions of overlapping components may be omitted.

Referring to FIGS. 1, 2A, 4A, 4B, 4C and 4D, a film substrate 100 is prepared. The film substrate 100 may be a base film. The film substrate 100 may include a chip region CR and bypass regions BR spaced apart from each other in the first direction D1 with the chip region CR therebetween. The film substrate 100 may include a first cut line CL1 and a second cut line CL2 extending along the first direction D1. The first cut line CL1 and the second cut line CL2 may be spaced apart from each other in the second direction D2. A region between the first cut line CL1 and the second cut line CL2 may be referred to as an inner side of the first cut line CL1, and a region extending from the first cut line CL1 in the second direction D2 may be referred to as an outer side of the first cut line CL1.

A dry film DF may be applied onto the film substrate 100. The dry film DF may include, for example, a photosensitive resin or a thermosetting resin. A portion of the film substrate 100 may be exposed by patterning the dry film DF through an exposure process using a mask pattern (not shown). Accordingly, first to third openings OP1, OP2 and OP3 may be formed. The first opening OP1 may be formed in the bypass region BR, and the second and third openings OP2 and OP3 may be formed in the chip region CR.

Referring to FIGS. 1, 2A, 5A, 5B, 5C and 5D, the first to third openings OP1, OP2 and OP3 may be filled by depositing a conductive material through a plating process. In this case, the dry film DF may be used as a plating mask. Accordingly, first and second connection lines 410 and 420 and bypass patterns BPP may be formed.

The bypass patterns BPP may each include a pattern part BL1, a line part BL2 and a dummy part BL3. The line part BL2 may extend between the pattern part BL1 and the dummy part BL3. The pattern part BL1 may be located on the inner side of the first cut line CL1. The pattern part BL1 may include first, third, fifth and seventh portions BL1_1, BL1_2, BL1_3 and BL1_4. The dummy part BL3 may be located on the outer side of the first cut line CL1. The dummy part BL3 may include first to fourth dummy portions BL3_1, BL3_2, BL3_3 and BL3_4. The first cut line CL1 may cross the line part BL2. The line part BL2 may include second, fourth, sixth and eighth portions BL2_1, BL2_2, BL2_3 and BL2_4. Each of the second, fourth, sixth and eighth portions BL2_1, BL2_2, BL2_3 and BL2_4 may be provided in plurality.

Referring to FIGS. 1, 2A, 6A, 6B, 6C and 6D, the dry film DF may be removed from the film substrate 100. As a result, a first recess R1 may be formed between the second portions BL2_1. A second recess R2 may be formed between the fourth portions BL2_2. A third recess R3 may be formed between the sixth portions BL2_3. A fourth recess R4 may be formed between the eighth portions BL2_4. Side surfaces of the first to fourth recesses R1, R2, R3 and R4 located on the outer side of the first cut line CL1 may be located at the same fifth distance DS5 from the first cut line CL1.

Thereafter, the first connection lines 410, the second connection lines 420 and the bypass patterns BPP may be cut along the first cut line CL1 and the second cut line CL2. The first and second connection pads 310 and 320 and the first and second bypass pads 330 and 340 respectively connected to the first connection lines 410, the second connection lines 420 and the bypass patterns BPP may be formed. The line protective layer 510 which covers the first connection lines 410, the second connection lines 420 and the bypass patterns BPP may be formed. The line protective layer 510 may be formed between the first cut line CL1 and the second cut line CL2 and may not cover the first and second connection pads 310 and 320 and the first and second bypass pads 330 and 340. Accordingly, the film package 1000 of FIG. 1 may be manufactured.

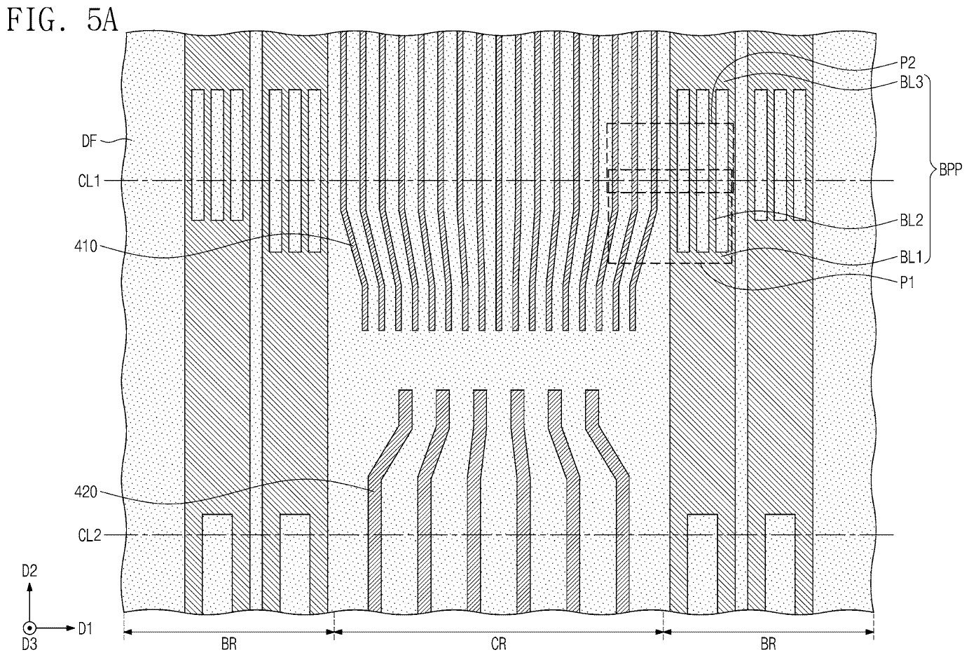

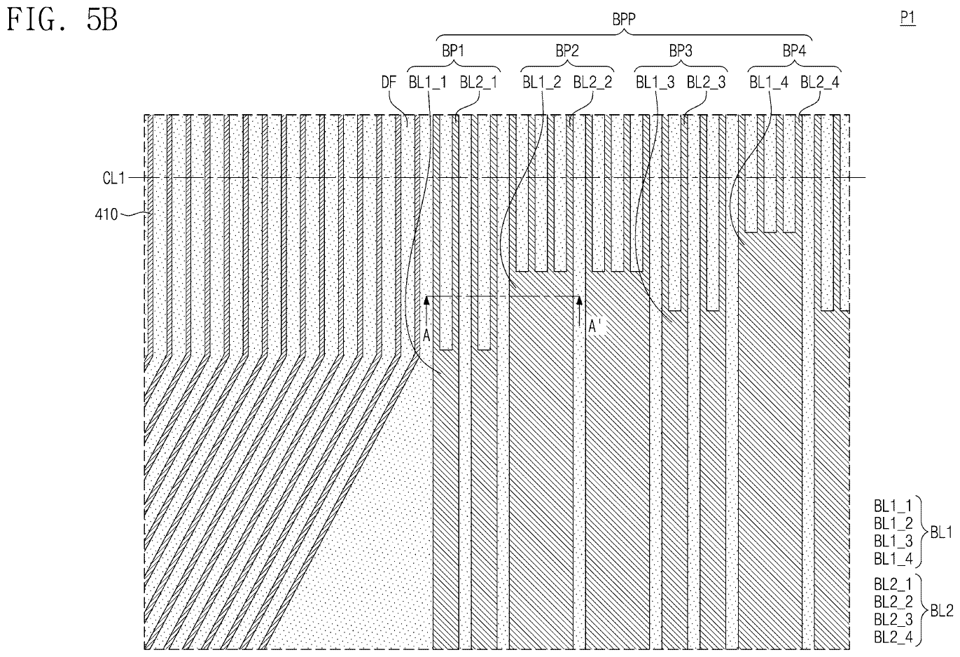

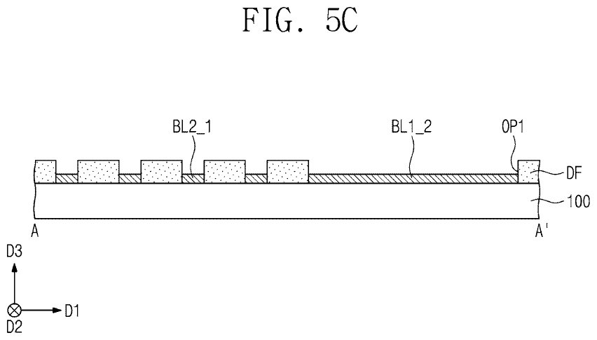

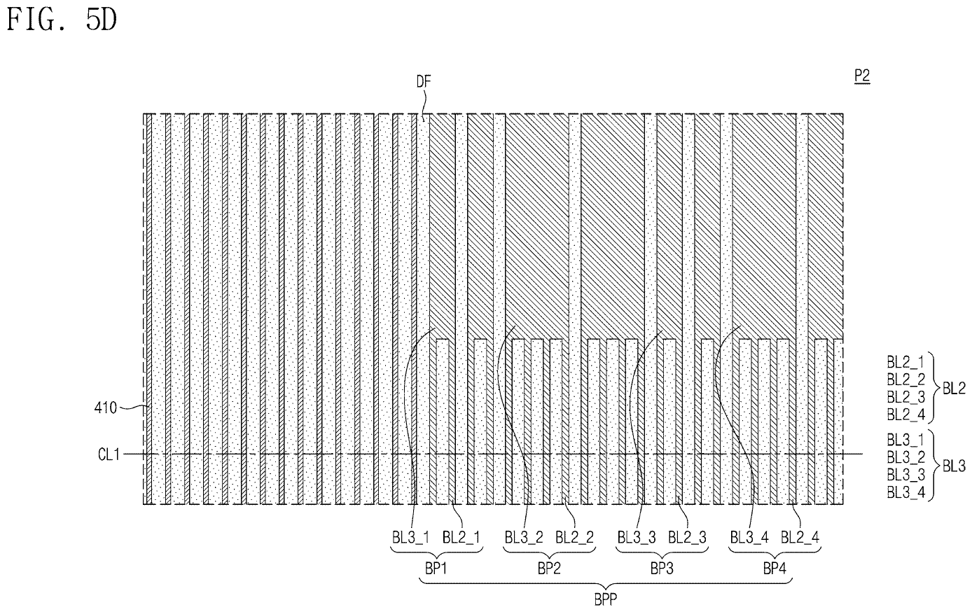

In the above process, for example, the first opening OP1 may be formed by patterning the dry film DF so that the fourth portions BL2_2 of FIG. 2A have the same length in the second direction D2, and thus dry films DF in the first opening OP1 may serve to support each other (see FIGS. 4A to 4D). In addition, the fourth portions BL2_2 may have the same length in the second direction D2, and thus the fourth portions BL2_2 may serve to support the dry film DF therebetween (see FIGS. 5A to 5D). Thus, when various processes (for example, wet etching, etc.) are performed, the dry film DF located in the first opening OP1 and between the fourth portions BL2_2 may be prevented from collapsing or being peeled off. Accordingly, a film package with improved reliability and a package module including the same may be provided.

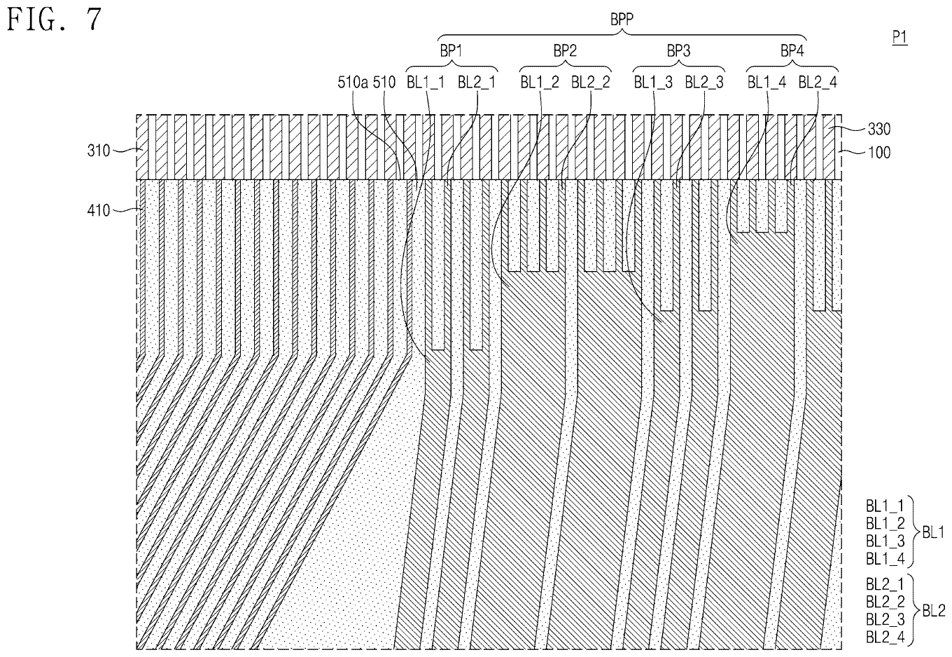

FIG. 7 is an enlarged view of portion P1 of FIG. 1.

Referring to FIGS. 1 and 7, each of the first to fourth bypass patterns BP1, BP2, BP3 and BP4, or at least one of them, may have a bent shape. In particular, the first, third, fifth and seventh portions BL1_1, BL1_2, BL1_3 and BL1_4 of the first to fourth bypass patterns BP1, BP2, BP3 and BP4 may be bent. That is, the pattern part BL1 of the bypass pattern BPP of FIG. 1 may have a bent shape. Alternatively, unlike the illustration, the line part BL2 of the bypass pattern BPP may have a bent shape. Angles and inflection points at which the first to fourth bypass patterns BP1, BP2, BP3 and BP4 are bent may be the same or different from one another. Other configurations may be the same as/similar to those described with reference to FIGS. 1 to 3B.

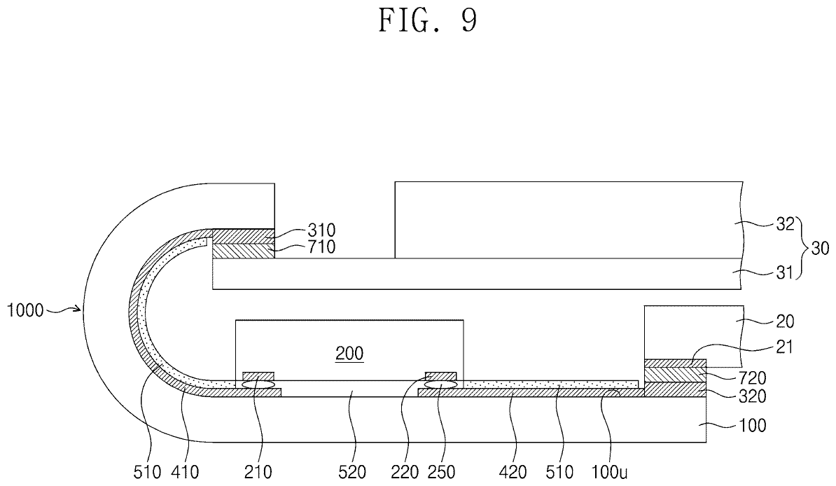

FIG. 8 is a plan view of a package module according to embodiments of the inventive concept. FIG. 9 is a cross-sectional view of a package module according to embodiments of the inventive concept. For simplification of descriptions, descriptions of overlapping components may be omitted.

Referring to FIGS. 1, 8 and 9, the package module may include a plurality of film packages 1000, a circuit board 20 and a display element 30. Each of the film packages 1000 may be the film package 1000 described with reference to FIGS. 1 to 7. The package module may be a display device assembly.

As in FIG. 9, a film substrate 100 may be flexible and bendable. For example, a portion of a front surface 100u of the film substrate 100 provided with a semiconductor chip 200 may face another portion of the front surface 100u.

The circuit board 20 may be disposed on the front surface 100u of the film substrate 100. The circuit board 20 may be adjacent to one side (the second edge 100b of FIG. 1) of the film substrate 100. For example, the circuit board 20 may be a printed circuit board (PCB) or a flexible printed circuit board (FPCB). An input connection part 720 may be interposed between second connection pads 320 and substrate pads 21 of the circuit board 20 and electrically connect the second connection pads 320 and the circuit board 20. Input connection parts 720 may include an anisotropic conductive film (ACF). Alternatively, the input connection parts 720 may include a solder ball or a solder bump. The circuit board 20 may be electrically connected to the semiconductor chip 200 via the second connection pads 320 and second connection lines 420.

The display element 30 may be disposed on the front surface 100u of the film substrate 100. The display element 30 may include a display substrate 31 and a display panel 32. The display element 30 may be adjacent to the other side (the first edge 100a of FIG. 1) of the film substrate 100. The display element 30 may cover an upper surface of the semiconductor chip 200. More specifically, the display substrate 31 may cover the upper surface of the semiconductor chip 200. An output connection part 710 may be interposed between first connection pads 310 and the display panel 32 and electrically connect the first connection pads 310 and the display panel 32. Output connection parts 710 may be an anisotropic conductive film. Alternatively, the output connection parts 710 may include a solder ball or a solder bump. The display element 30 may be electrically connected to the semiconductor chip 200 via the first connection pads 310 and first connection lines 410.

The semiconductor chip 200 may be supplied with a signal from the circuit board 20 via the second connection pads 320 and the second connection lines 420. The semiconductor chip 200 may include driving integrated circuits (for example, a gate driving integrated circuit and/or a data driving integrated circuit) and generate a driving signal (for example, a gate driving signal and/or a data driving signal). The driving signal generated in the semiconductor chip 200 may be supplied to a gate line and/or a data line of the display element 30 via the first connection pads 310 and the first connection lines 410. Accordingly, the display element 30 may be driven.

Chip terminals 250 may be arranged between a portion of the first connection line 410 and a first chip pad 210 and between a portion of the second connection line 420 and a second chip pad 220. The semiconductor chip 200 may be electrically connected to the first connection line 410 and the second connection line 420 via the chip terminals 250. Each of the chip terminals 250 may be at least one of a solder, a pillar or a bump. The chip terminals 250 may include metal.

A line protective layer 510 may cover the front surface 100u of the film substrate 100. The line protective layer 510 may be spaced apart from the semiconductor chip 200. An underfill layer 520 may be formed in a gap between the film substrate 100 and the semiconductor chip 200 and fill the gap. The underfill layer 520 may seal the chip terminals 250. The underfill layer 520 may be interposed between the chip terminals 250 and the line protective layer 510. The underfill layer 520 may include an insulating polymer such as an epoxy-based polymer.

In a film package according to the inventive concept, a bypass pattern may include one first portion and a plurality of second portions extending from the first portion and spaced apart from each other. Since the second portions have the same length, a dry film located between the second portions may be prevented from collapsing or being peeled off in a process of manufacturing the film package.

In addition, since a plurality of bypass patterns respectively have the second portions having lengths different from each other, stress may be distributed, and thus a crack or disconnection of the bypass patterns due to bending stress may be prevented.

In an embodiment of the inventive concept, a method for manufacturing a film package includes forming a dry film on a film substrate, patterning the dry film by using a mask pattern and forming openings exposing the film substrate, filling the openings by depositing a conductive material, forming first connection lines, second connection lines and bypass patterns by removing the dry film, and cutting the first connection lines, second connection lines and bypass patterns along a first cut line.

In an embodiment, the bypass patterns may each include a first portion on an inner side of the first cut line, a second portion on an outer side of the first cut line, and a plurality of third portions extending between the first portion and the second portion and spaced apart from each other along a first direction parallel to the first cut line.

In an embodiment, recesses may be formed between the third portions, and side surfaces of the recesses on an outer side of the first cut line may be located at a same distance from the first cut line.

Although the embodiments of the inventive concept have been described with reference to the accompanying drawings, the inventive concept may be carried out in other specific forms without changing the technical concept or essential features. Therefore, it should be understood that the embodiments described above are illustrative and non-limiting in all respects.

What is claimed is:

1. A film package comprising:
a film substrate including a chip region, bypass regions spaced apart from one another in a first direction with the chip region disposed therebetween, and a first edge and a second edge opposing each other in a second direction intersecting the first direction;
first bypass pads arranged on the bypass region adjacent to the first edge and second bypass pads arranged on the bypass region adjacent to the second edge; and
a first bypass pattern connecting the first bypass pads and the second bypass pads,
wherein the first bypass pattern includes:
a first portion,
a plurality of second portions extending from the first portion, connected to the first bypass pads, and spaced apart from one another, and
a plurality of first recesses each defined between an adjacent pair of second portions among the plurality of second portions,
wherein the second portions have a same first length in the second direction, and
wherein a distance between outer side surfaces of second portions, spaced farthest apart from each other among the second portions in the first direction, is equal to a first width of the first portion in the first direction.

2. The film package of claim 1, wherein the first recesses have the first length from ends of the second portions.

3. The film package of claim 1, further comprising a second bypass pattern located to be spaced apart from the first bypass pattern in the first direction,
wherein the second bypass pattern includes a third portion and a plurality of fourth portions extending from the third portion, connected to the first bypass pads, and spaced apart from one another,
wherein the fourth portions have a same second length in the second direction, and
wherein the second length is greater than the first length. The film package of claim 3, wherein a number of the plurality of fourth portions two, and wherein the second bypass pattern is provided in plural, wherein the plurality of second bypass patterns are spaced apart from one another, and two or more of the plurality of second bypass patterns are continuously arranged on the film substrate.

5. The film package of claim 3, wherein a difference between the first length and the second length is about 50 μm to about 500 μm.

6. The film package of claim 3, further comprising a third bypass pattern located to be spaced apart from the first and second bypass patterns in the first direction,
wherein the third bypass pattern includes a fifth portion and a plurality of sixth portions extending from the fifth portion, connected to the first bypass pads, and spaced apart from one another,
wherein the sixth portions have a same third length in the second direction, and
wherein the third length is smaller than the second length and greater than the first length.

7. The film package of claim 1, wherein the first bypass pattern has a bent shape.

8. The film package of claim 1, further comprising:
first connection pads arranged on the chip region adjacent to the first edge and second connection pads arranged on the chip region adjacent to the second edge; and
a semiconductor chip disposed between the first and second connection pads on the chip region,
wherein the semiconductor chip includes:
first chip pads connected to the first connection pads via first connection lines, and
second chip pads connected to the second connection pads via second connection lines.

9. The film package of claim 8, wherein the first connection pads are configured as output pads, and
wherein the second connection pads are configured as input pads.

10. A film package comprising:
a film substrate including a chip region, bypass regions spaced apart from one another in a first direction with the chip region disposed therebetween, and a first edge and a second edge opposing each other in a second direction intersecting the first direction;
first bypass pads arranged on the bypass region adjacent to the first edge and second bypass pads arranged on the bypass region adjacent to the second edge; and
first bypass patterns connecting the first bypass pads and the second bypass pads and spaced apart from one another in the first direction,
wherein each of the first bypass patterns includes:
a first portion, and
a plurality of second portions extending from the first portion, connected to the first bypass pads, and spaced apart from one another,
wherein the second portions have a same first length in the second direction, and
wherein two or more of the first bypass patterns are continuously arranged on the film substrate.

11. The film package of claim 10, further comprising first connection pads arranged on the chip region adjacent to the first edge and second connection pads arranged on the chip region adjacent to the second edge.

12. The film package of claim 11, further comprising a semiconductor chip disposed between the first connection pads and the second connection pads on the chip region,
wherein the semiconductor chip includes:
first chip pads connected to the first connection pads via first connection lines; and
second chip pads connected to the second connection pads via second connection lines,
wherein the first connection pads are configured as output pads, and
wherein the second connection pads are configured as input pads.

13. The film package of claim 12, wherein the first and second connection lines are arranged on the chip region, and
wherein the first and second connection lines are spaced apart from the first bypass patterns.

14. The film package of claim 12, further comprising a line protective layer which covers the first and second connection lines and the first bypass patterns.

15. The film package of claim 10, further comprising second bypass patterns located to be spaced apart from the first bypass patterns in the first direction,
wherein the second bypass pattern includes a third portion and a plurality of fourth portions extending from the third portion, connected to the first bypass pads, and spaced apart from one another,
wherein the fourth portions have a same second length in the second direction, and
wherein the first length is greater than the second length.

16. The film package of claim 10, further comprising a second bypass pattern located to be spaced apart from the first bypass patterns in the first direction,
wherein the second bypass pattern includes:
a third portion including a first sub-portion and a second sub-portion; and
a plurality of fourth portions extending from the third portion, connected to the first bypass pads, and spaced apart from one another,
wherein the fourth portions connected to the first sub-portion have a same second length in the second direction,
wherein the fourth portions connected to the second sub-portion have a same third length in the second direction, and
wherein the second length is different from the third length.

17. A package module comprising:
a circuit board;
a display panel spaced apart from the circuit board; and
a film package disposed between the circuit board and the display panel,
wherein the film package includes:
a film substrate including a chip region, bypass regions spaced apart from each other in a first direction with the chip region disposed therebetween, and a first edge and a second edge opposing each other in a second direction intersecting the first direction,
first connection pads arranged adjacent to the first edge and connected to the display panel and second connection pads arranged adjacent to the second edge and connected to the circuit board, on the chip region,
a semiconductor chip disposed between the first and second connection pads on the chip region,
first bypass pads arranged on the bypass region adjacent to the first edge and second bypass pads arranged on the bypass region adjacent to the second edge, and
a first bypass pattern and a second bypass pattern connecting the first bypass pads and the second bypass pads, and spaced apart from each other in the first direction,
wherein the first bypass pattern includes:
a first portion, and
a plurality of second portions extending from the first portion, connected to the first bypass pads, and spaced apart from one another,
wherein the second bypass pattern includes:
a third portion, and
a plurality of fourth portions extending from the third portion and connected to the first bypass pads,
wherein the second portions have a same first length in the second direction,
wherein the fourth portions have a same second length in the second direction, and
wherein the first length is greater than the second length.

18. The package module of claim 17, wherein a difference between the first length and the second length is about 50 μm to about 500 μm.

19. The package module of claim 17, wherein a number of the plurality of second portions is two, and
wherein the first bypass pattern is provided in plural, wherein the plurality of first bypass patterns are spaced apart from one another, and two or more of the plurality of first bypass patterns are continuously arranged on the film substrate.

20. The package module of claim 17, further comprising a display element, wherein the display element covers an upper surface of the semiconductor chip.
